(19) United States
(12) Patent Application Publication
(10) Pub. No.: US 2025/0316304 A1
(43) Pub. Date: Oct. 9, 2025

(54) INTEGRATED CIRCUIT PACKAGE AND OPERATION METHOD THEREOF

(71) Applicant: Samsung Electronics Co., Ltd., Suwon-si (KR)

(72) Inventor: JUNGPIL LEE, Suwon-si (KR)

(21) Appl. No.: 19/037,127

(22) Filed: Jan. 25, 2025

(30) Foreign Application Priority Data
Apr. 9, 2024 (KR) 10-2024-0048067

(51) Int. Cl. G11C 11/4076; H01L 23/538; H01L 25/16; H10B 80/00

(52) U.S. Cl. CPC G11C 11/4076; H01L 25/16; H01L 23/538; H01L 2225/06513; H01L 2225/06517; H01L 2225/06541; H10B 80/00

(57) ABSTRACT

An integrated circuit package may include a substrate, a first semiconductor chip disposed on the substrate and configured to output a first clock signal and a first data signal, a delay circuit configured to delay at least one of the first clock signal and the first data signal, and to output a second clock signal and a second data signal based on the first clock signal and the first data signal, and a second semiconductor chip disposed on the substrate to be horizontally spaced apart from the first semiconductor chip and configured to receive the second clock signal and the second data signal.

### CROSS-REFERENCE TO RELATED APPLICATION(S)

This application claims priority to and the benefit of Korean Patent Application No. 10-2024-0048067 filed in the Korean Intellectual Property Office on Apr. 9, 2024, the disclosure of which is incorporated herein by reference in its entirety.

### BACKGROUND

### (a) Field of the Invention

The present invention relates to an integrated circuit package and an operation method thereof.

### (b) Description of the Related Art

As electronic products become smaller, multi-functional, and high-performance, there is also a demand for the packaging to be lighter, more integrated, higher performing, and faster. Therefore, demand is increasing for integrated circuit packages that can implement systems with high data bandwidth, and accordingly, the data input/output speed within these packages is also increasing.

As the data input/output speed increases, the data-valid window margin decreases, and the increased density of data patterns leads to increased coupling noise, which deteriorates the signal integrity of the data signals, resulting in a need to improve this situation.

### SUMMARY

The present invention attempts to provide an integrated circuit package and an operation method thereof capable of improving a margin of a data-valid window with respect to data signal transmitted and received between chips.

The present invention attempts to provide an integrated circuit package and an operation method thereof capable of improving skews between the data signal and the clock signal transmitted and received synchronously between chips.

According to example embodiments, an integrated circuit package may include a substrate, a first semiconductor chip disposed on the substrate and configured to output a first clock signal and a first data signal, on the substrate, a delay circuit configured to delay at least one of the first clock signal and the first data signal, and to output a second clock signal and a second data signal based on the first clock signal and the first data signal, and a second semiconductor chip disposed on the substrate to be horizontally spaced apart from the first semiconductor chip and configured to receive the second clock signal and the second data signal.

According to example embodiments, an integrated circuit package may include a first semiconductor chip configured to output a first clock signal and a first data signal, an active interposer connected to the first semiconductor chip, and including a delay circuit configured to delay at least one of the first clock signal and the first data signal, and to output a second clock signal and a second data signal, and a second semiconductor chip disposed on the active interposer to be horizontally spaced apart from the first semiconductor chip, and configured to receive the second clock signal and the second data signal.

According to example embodiments, an operation method of an integrated circuit package may include receiving an input/output tuning command from a first semiconductor chip mounted on a substrate, receiving a first clock signal and a first data signal from the first semiconductor chip, in response to the reception of the input/output tuning command, performing an input/output tuning operation by delaying at least one of the first clock signal and the first data signal to output a second clock signal and second data signal, checking a data-valid section with respect to the second data signal, based on the second clock signal and the second data signal, setting a delay setting value with respect to the input/output tuning operation, in response to result of the checking, and outputting the second clock signal and the second data signal, based on the delay setting value.

### BRIEF DESCRIPTION OF THE DRAWINGS

FIG. 1 is a block diagram showing an integrated circuit package according to an embodiment.

FIG. 2 is a block diagram showing an integrated circuit package according to an embodiment.

FIG. 3 is a circuit diagram showing a delay circuit according to an embodiment.

FIG. 4 is a drawing for explaining an integrated circuit package according to an embodiment.

FIG. 5 is a flowchart showing an operation method of an integrated circuit package according to an embodiment.

FIG. 6 is a timing diagram for explaining an input/output tuning operation of an integrated circuit package according to an embodiment.

FIG. 7 is a timing diagram for explaining an input/output tuning operation of an integrated circuit package according to an embodiment.

FIG. 8 is a block diagram showing an integrated circuit package according to an embodiment.

FIG. 9 is a flowchart showing an operation method of an integrated circuit package according to an embodiment.

FIG. 10 is a drawing for explaining an integrated circuit package according to an embodiment.

FIG. 11 is a drawing for explaining an integrated circuit package according to an embodiment.

### DETAILED DESCRIPTION OF THE EMBODIMENTS

Hereinafter, the present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, unless explicitly described to the contrary, the word “comprise”, and variations such as “comprises” or “comprising”, will be understood to imply the inclusion of stated elements but not the exclusion of any other elements.

Additionally, specific numbers described in a claim, even if explicitly recited within the claim, should not be construed as limiting the specific number in claims where such citation does not exist. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

Furthermore, in those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In an embodiment, ‘a module’, ‘a unit’, or ‘a part’ perform at least one function or operation, and may be realized as hardware, such as a processor or integrated circuit, software that is executed by a processor, or a combination thereof.

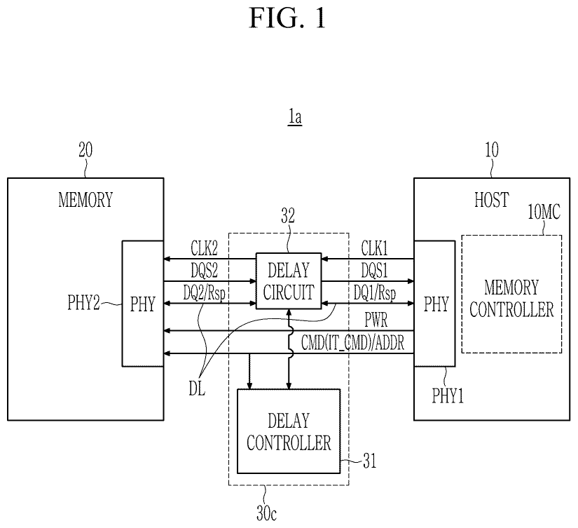

FIG. 1 is a block diagram showing an integrated circuit package according to an embodiment.

Referring to FIG. 1, an integrated circuit package 1a may include a host device 10, a memory device 20, and an input/output tuning circuit 30c. In an embodiment, the integrated circuit package 1a may be a memory system. The host device 10 and the memory device 20 may be connected through physical layers PHY1 and PHY2 and the input/output tuning circuit 30c, and may transmit data signals DQ1 and DQ2 synchronously with clock signals CLK1 and CLK2.

The host device 10 may provide a command CMD, an address ADDR, and a power signal PWR to the memory device 20 through the physical layers PHY1 and PHY2. In an embodiment, the host device 10 may be provided with a response signal Rsp with respect to the command CMD from the memory device 20, through data line DL through which the data signals DQ1 and DQ2 are transmitted and received. In an embodiment, the host device 10 may provide an input/output tuning command IT_CMD to the memory device 20 and the input/output tuning circuit 30c.

In an embodiment, the host device 10 may output the input/output tuning command IT_CMD according to a boot-on time point of the integrated circuit package 1a or predetermined tuning update cycle. In an embodiment, the host device 10 may provide a tuning block signal for an input/output tuning operation to the input/output tuning circuit 30c, after transmitting the input/output tuning command IT_CMD. The tuning block signal may include a first clock signal CLK1 and a first data signal DQ1. In an embodiment, the host device 10 may be provided with the response signal Rsp and a data strobe signal DQS1 with respect to the input/output tuning command IT_CMD, through the data line DL.

In an embodiment, the host device 10 may provide the first clock signal CLK1 and the first data signal DQ1 to the input/output tuning circuit 30c, through a first physical layer PHY1. In an embodiment, the input/output tuning circuit 30c may perform the input/output tuning operation according to the reception of the input/output tuning command IT_CMD, and may output a second clock signal CLK2 and second data signal DQ2 based on the first clock signal CLK1 and the first data signal DQ1. In an embodiment, the outputted second clock signal CLK2 and the second data signal DQ2 may be provided to the memory device 20 through a second physical layer PHY2.

The host device 10 may include the first physical layer PHY1 and a memory controller 10MC. The host device 10 may be in the form of a separate logic semiconductor chip or a plurality of semiconductor chiplets. In an embodiment, the host device 10 may be a system on chip (SoC), a graphics processing unit (GPU) die, a central processing unit (CPU) die, or the like, and in an embodiment, the memory controller 10MC may be embedded in the host device 10.

The memory controller 10MC may provide various signals to the memory device 20 through the first physical layer PHY1, to control a memory operation such as a write operation and a read operation.

The memory controller 10MC may output the first clock signal CLK1, the command CMD, the address ADDR, and the power signal PWR to the memory device 20 through the first physical layer PHY1, may transmit and receive the data signals DQ1, and may receive the data strobe signal DQS1 with respect to the memory device 20 through the first physical layer PHY1.

The first physical layer PHY1 may be a physical layer (hereinafter, PHY), which is a lowermost layer, as a configuration of an interface for die-to-die communication. In an embodiment, the first physical layer PHY1 may be a physical layer of a high-speed interface in a serial scheme. In an embodiment, the first physical layer PHY1 may be one of HBM2E/2 PHY, HBM3 PHY, HBI PHY, DDR5/4 PHY, USR/XSR PHY, and I3C PHY of MIPI, complying with JEDEC HBM, but is not limited thereto.

In an embodiment, in order to transmit data, the first physical layer PHY1 may physically connect between systems and perform conversion and control of electrical signals, synchronization of clock signal, link training, or the like, and may control the configuration related to the sideband transmitting the clock signal, or the like.

In an embodiment, the memory device 20 may be a high bandwidth memory (HBM) device including a plurality of memory channels, but is not limited thereto, and may be a dynamic random-access memory (DRAM) such as double data rate synchronous dynamic random-access memory (DDR SDRAM), low-power double data rate (LPDDR) SDRAM, graphics double data rate (GDDR) SDRAM, Rambus dynamic random-access memory (RDRAM), or the like.

The memory device 20 may, through the second physical layer PHY2, receive the command CMD, the address ADDR, and the power signal PWR from the host device 10, receive the second clock signal CLK2 from the input/output tuning circuit 30c, transmit and receive the second data signal DQ2 to and from the input/output tuning circuit 30c, and transmit the second data strobe signal DQS2 to the input/output tuning circuit 30c. In an embodiment, the second physical layer PHY2 may correspond to the first physical layer PHY1, may be one of HBM2E/2 PHY, HBM3 PHY, HBI PHY, DDR5/4 PHY, USR/XSR PHY, and I3C PHY of MIPI complying with JEDEC HBM, but is not limited thereto.

Although not shown, the second physical layer PHY2 may include a serializer/deserializer. The second physical layer PHY2 may perform read and write operation based on the number of data pads disposed in the second physical layer PHY2 through the serializer/deserializer. The memory device 20 may perform deserialization and serialization with respect to data signal according to the write operation and read operation, through the serializer/deserializer.

The input/output tuning circuit 30c may include a delay controller 31 and a delay circuit 32. In an embodiment, the input/output tuning circuit 30c may perform the input/output tuning operation for delaying at least one of the first data signal DQ1 and the first clock signal CLK1 received from the host device 10, and may output the second clock signal CLK2 and the second data signal DQ2.

In an embodiment, the delay controller 31 may receive the input/output tuning command IT_CMD from the host device 10, and may control the delay circuit 32 by outputting a selection signal SS in response to the reception of the input/output tuning command IT_CMD.

In an embodiment, the delay controller 31 may receive the second clock signal CLK2 and the second data signal DQ2 output by the input/output tuning operation of the delay circuit 32, and may check the data-valid section with respect to the second data signal DQ2.

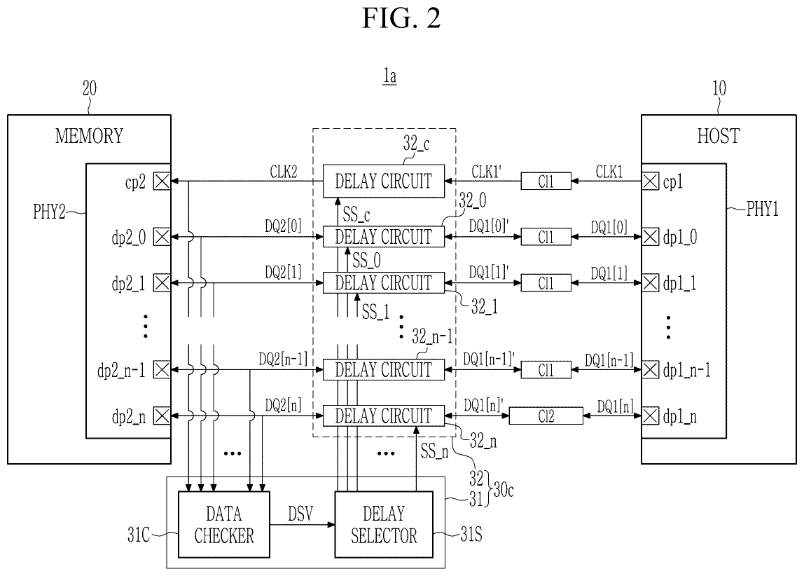

In an embodiment, the delay controller 31 may determine a completion of the input/output tuning operation, according to the result of the check operation with respect to the data-valid section. In an embodiment, the delay controller 31 may provide the result of the determination to the host device 10 as the response signal Rsp. In an embodiment, the delay controller 31 may set a delay setting value DSV in response to the completion of the input/output tuning operation, and may output the selection signal SS based on a predetermined delay setting value DSV to provide it to the delay circuit 32. Detailed configuration and operation of the delay controller 31 will be described later in the description with reference to FIG. 2 to FIG. 7.

In an embodiment, the delay circuit 32 may be provided with the selection signal SS from the delay controller 31, and may perform the input/output tuning operation for delaying at least one of the first clock signal CLK1 and the first data signal DQ1 based on the selection signal SS. Based on the input/output tuning operation, the delay circuit 32 may output the second clock signal CLK2 and the second data signal DQ2.

Thereafter, the delay circuit 32 may be provided with the selection signal SS based on the predetermined delay setting value DSV. In an embodiment, when the first clock signal CLK1 and the first data signal DQ1 are provided together with the write command from the host device 10, the delay circuit 32 may perform the input/output tuning operation by the selection signal SS based on the predetermined delay setting value DSV, to output the second clock signal CLK2 and the second data signal DQ2. Detailed configuration and operation of the delay circuit 32 will be described later in the description with reference to FIG. 2 to FIG. 7.

FIG. 2 is a block diagram showing an integrated circuit package according to an embodiment. Specifically, FIG. 2 is a drawing for explaining the connection relationship between the host device 10, the memory device 20, and the input/output tuning circuit 30c, focusing on the clock signals CLK1 and CLK2 and the data signals DQ1 and DQ2.

Referring to FIG. 1 and FIG. 2, the delay controller 31 may include a delay selector 31S and data checker 31C. The delay circuit 32 may include a clock delay circuit 32_c and 0-th to n-th delay circuits 32_0 to 32_n (n is a natural number equal to or greater than 1).

The delay circuit 32 may receive the first clock signal CLK1 and the first data signal DQ1 from the host device 10 as the delay clock signal and the delay data signal. In an embodiment, the first data signal DQ1 may include 1_0-th to 1_n-th data signals DQ1[n:0], and each of the 1_0-th to 1_n-th data signals DQ1[n:0] may include 1 bit of data. In an embodiment, the first clock signal CLK1 and each of the 1_0-th to 1_n-th data signals DQ1[n:0] may be output from a first clock pad cp1 and 1_0-th to 1_n-th data pads dp1_0 to dp1_n of the first physical layer PHY1, respectively, and may be provided to the clock delay circuit 32_c and the 0-th to n-th delay circuits 32_0 to 32_n, respectively. The above-mentioned n may be one of 15, 31, and 63, but is not limited thereto.

In an embodiment, by the wire between each first clock pad cp1 and the 1_0-th to 1_n-th data pads dp1_0 to dp1_n and each clock delay circuit 32_c and the 0-th to n-th delay circuits 32_0 to 32_n, the first clock signal CLK1 and the 1_0-th to 1_n-th data signals DQ1[n:0] may be delayed and input to the clock delay circuit 32_c and the 0-th to n-th delay circuits 32_0 to 32_n as a first delay clock signal CLK1′ and 1_0-th to 1_n-th delay data signals DQ1[n:0]′, respectively.

With an example of FIG. 2, the first clock signal CLK1 and each of 1_0-th to 1_n-1-th data signals DQ1[n-1:0] may be delayed by a first wire capacitor Cl1, and may be provided to the clock delay circuit 32_c and 0-th to n-1-th delay circuits 32_0 to 32_n-1 as the first delay clock signal CLK1′ and 1_0-th to 1_n-1-th delay data signals DQ1[n-1:0]′. In addition, a 1_n-th data signal DQ1[n] may be delayed by a second wire capacitor Cl2, and may be provided to a n-th delay circuit 32_n as a 1_n-th delay data signal DQ1[n]′.

The clock delay circuit 32_c and each of the 0-th to n-th delay circuits 32_0 to 32_n may be provided with a clock selection signal SS_c and 0-th to n-th selection signals SS_0 to SS_n from the delay selector 31S, respectively. In an embodiment, the clock delay circuit 32_c and the 0-th to n-th delay circuits 32_0 to 32_n may perform a delay operation with respect to the first delay clock signal CLK1′ and the 1_0-th to 1_n-th delay data signals DQ1[n:0]′ based on the clock selection signal SS_c and the 0-th to n-th selection signals SS_0 to SS_n. Through the delay operation, the clock delay circuit 32_c and each of the 0-th to n-th delay circuits 32_0 to 32_n may output the second clock signal CLK2 and 2_0-th to 2_n-th data signals DQ2[n:0], respectively.

In an embodiment, based on the clock selection signal SS_c and the 0-th to n-th selection signals SS_0 to SS_n, the clock delay circuit 32_c and each of the 0-th to n-th delay circuits 32_0 to 32_n may perform the delay operation individually. As described above, through individual operation of the clock delay circuit 32_c and the 0-th to n-th delay circuits 32_0 to 32_n, the delay circuit 32 may perform the input/output tuning operation.

In an embodiment, the second clock signal CLK2 and each of the 2_0-th to 2_n-th data signals DQ2[n:0] generated through the input/output tuning operation may be input to a second clock pad cp2 and 2_0-th to 2_n-th data pads dp2_0 to dp2_n of the second physical layer PHY2, respectively. In an embodiment, the second clock signal CLK2 and the 2_0-th to 2_n-th data signals DQ2[n:0] may be provided to the data checker 31C. In an embodiment, the data checker 31C may receive the second clock signal CLK2 and the 2_0-th to 2_n-th data signals DQ2[n:0], and based on these, may check the data-valid section with respect to the second data signal DQ2.

In an embodiment, the data checker 31C may determine the completion of the input/output tuning operation, according to the result of the check operation with respect to the data-valid section. In an embodiment, the data checker 31C may provide the result of the determination to the host device 10 as the response signal Rsp. In an embodiment, the data checker 31C may set the delay setting value DSV in response to the completion of the input/output tuning operation, and may provide the delay setting value DSV to the delay selector 31S.

In an embodiment, the delay selector 31S may provide the clock selection signal SS_c and the 0-th to n-th selection signals SS_0 to SS_n to the clock delay circuit 32_c and the 0-th to n-th delay circuits 32_0 to 32_n, respectively, according to the delay setting value DSV.

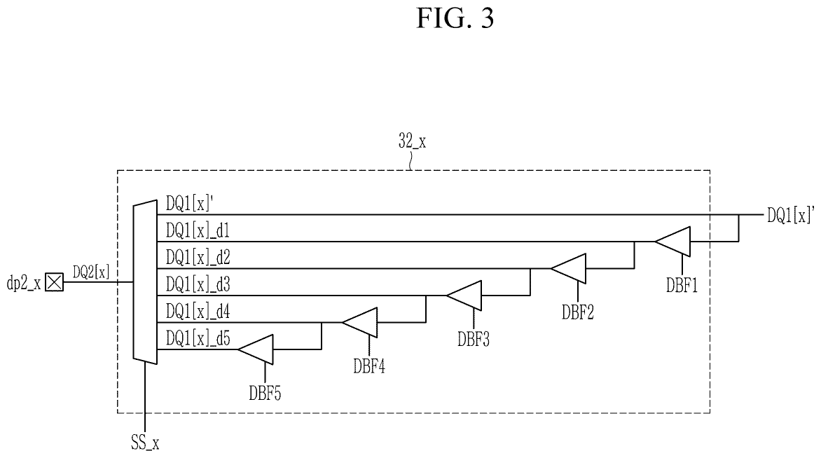

FIG. 3 is a circuit diagram showing a delay circuit according to an embodiment. An x-th the delay circuit 32_x of FIG. 3 may be one of the clock delay circuit 32_c and the 0-th to n-th delay circuits 32_0 to 32_n of FIG. 2. For ease of description, as a description for the x-th the delay circuit 32_x, the description on the clock delay circuit 32_c and the 0-th to n-th delay circuits 32_0 to 32_n may be applied.

Referring to FIG. 2 and FIG. 3, the x-th the delay circuit 32_x may include first to fifth delay buffers DBF1 to DBF5 and a multiplexer MUX.

In an embodiment, the first to fifth delay buffers DBF1 to DBF5 may be serially connected in the form of a chain between the input terminal of the x-th the delay circuit 32_x and one input end of the multiplexer MUX. In an embodiment, each of the first to fifth delay buffers DBF1 to DBF5 may delay the input signal by a predetermined delay time and output it. The predetermined delay time may be 1 ns to 10 ns, but is not limited thereto. In an embodiment, each of the first to fifth delay buffers DBF1 to DBF5 may include an inverter chain, but is not limited thereto. FIG. 3 illustrates that the number of delay buffers is 5, but this is merely an example and the spirit and scope of the present disclosure is not limited to the number of the delay buffers.

In an embodiment, when the x-th the delay circuit 32_x is the one of the 0-th to n-th delay circuits 32_0 to 32_n, a first delay buffer DBF1 may delay a 1_x-th delay data signal DQ1[x]′ by a predetermined delay time and output a first delay buffer signal DQ1[x]_d1. A second delay buffer DBF2 may delay the first delay buffer signal DQ1[x]_d1 by a predetermined delay time and output a second delay buffer signal DQ1[x]_d2. A third delay buffer DBF3 may delay the second delay buffer signal DQ1[x]_d2 by a predetermined delay time and output a third delay buffer signal DQ1[x]_d3. A fourth delay buffer DBF4 may delay the third delay buffer signal DQ1[x]_d3 by a predetermined delay time and output a fourth delay buffer signal DQ1[x]_d4. A fifth delay buffer DBF5 may delay the fourth delay buffer signal DQ1[x]_d4 by a predetermined delay time and output a fifth delay buffer signal DQ1[x]_d5.

The multiplexer MUX may receive the 1_x-th delay data signal DQ1[x]′ and first to fifth delay buffer signals DQ1[x]_d1 to DQ1[x]_d5, and may receive an x-th selection signal SS_x from the delay selector 31S. In an embodiment, the multiplexer MUX may select one of the 1_x-th delay data signal DQ1[x]′ and the first to fifth delay buffer signals DQ1[x]_d1 to DQ1[x]_d5 based on the x-th selection signal SS_x and output the selected delay data signal as a 2_x-th data signal DQ2[x]. The 2_x-th data signal DQ2[x] may be provided to a 2_x-th data pad dp2_x of the second physical layer PHY2.

In an embodiment, when the x-th the delay circuit 32_x is the clock delay circuit 32_c, the 1_x-th delay data signal DQ1[x]′ of FIG. 3 may correspond to the first delay clock signal CLK1′ of FIG. 2, the first to fifth delay buffer signals DQ1[x]_d1 to DQ1[x]_d5 of FIG. 3 may correspond to first to fifth delay buffer signals CLK1_d1 to CLK1_d5 (not shown), the 2_x-th data signal DQ2[x] of FIG. 3 may correspond to the second clock signal CLK2 of FIG. 2, and the 2_x-th data pad dp2_x of FIG. 3 may correspond to the second clock pad cp2 of FIG. 2.

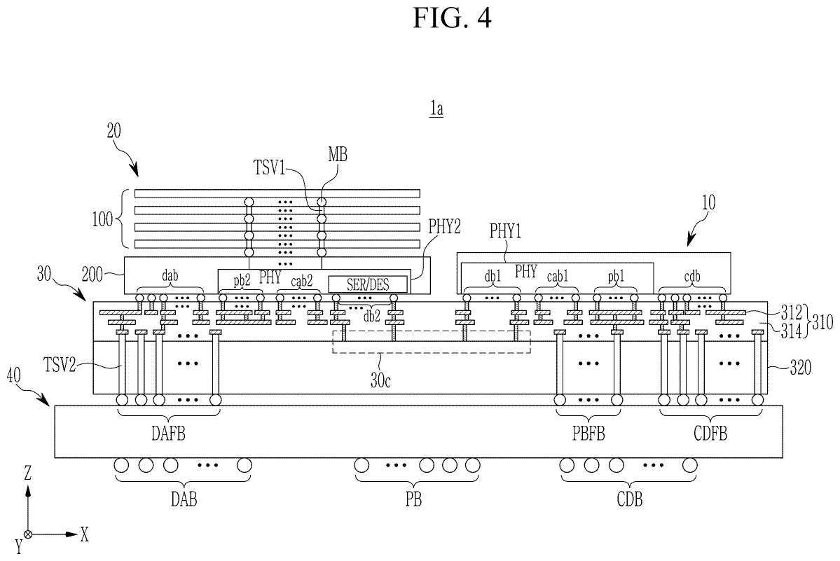

FIG. 4 is a drawing for explaining an integrated circuit package according to an embodiment. Referring to FIG. 1 to FIG. 4, the integrated circuit package 1a may include the host device 10, the memory device 20, an interposer 30, and a printed circuit board (hereinafter, PCB) 40.

The host device 10 and the memory device 20 may be arranged and mounted on the interposer 30. The host device 10 and the memory device 20 may be disposed to be spaced apart from each other in a first direction X, and non-overlapping with each other in a plan view with respect to a third direction Z.

A plurality of first command and address bumps cab1, a plurality of first data bumps db1, a plurality of first power bumps pb1, and a plurality of first control signal bumps cdb may be disposed on a lower surface of the host device 10. The host device 10 may include the first physical layer PHY1 connected to the plurality of first command and address bumps cab1, the plurality of first power bumps pb1, and the first data bump db1. The first data bump db1 according to an embodiment may be in contact with and connected to the 1_0-th to 1_n-th data pads dp1_0 to dp1_n connected to the data line DL in FIG. 1 and FIG. 2 and configured to transmit and receive the first data signal DQ1.

The memory device 20 may include a memory die 100 and a buffer die 200 that include four core dies stacked in the third direction Z. In an embodiment, each of the memory die 100 and the buffer die 200 may be implemented in the form of a semiconductor chip. A plurality of first bumps MB may be formed between the stacked core dies and the buffer die 200, and a first through-silicon via TSV1 penetrating the core dies may be formed between the stacked plurality of first bumps MB.

In an embodiment, unlike what is shown, the memory device 20 may include stacked five or more core dies, and in an embodiment, the buffer die 200 may be stacked in an upper portion, instead a lower portion, of the stacked core dies.

Although not shown, each of the stacked core dies may include the plurality of memory channels (not shown), and each of the plurality of memory channels (not shown) may include memory banks (not shown) of a predetermined quantity. Data terminals, command and address terminals, and electric power terminals may be disposed between the plurality of memory channels, and through the data terminals, the command and address terminals, and the electric power terminals, the second data signal DQ2, the command CMD, the address ADDR, and the power signal PWR may be input to and output from the plurality of memory channels. In an embodiment, the data terminals, the command and address terminals, and the electric power terminals may be connected to the second physical layer PHY2.

The data terminals, each of the command and address terminals and the electric power terminals may be the plurality of first bumps MB shown in FIG. 4. In an embodiment, conductors vertically penetrating the data terminals, the command and address terminals, and the electric power terminals may be the first through-silicon via TSV1.

With respect to the third direction Z as a reference, a plurality of first direct access bumps dab, a plurality of second power bumps pb2, a plurality of second command and address bumps cab2, and a plurality of second data bumps db2 may be disposed on a lower surface of the buffer die 200.

In addition, the buffer die 200 may include the plurality of second command and address bumps cab2, the plurality of second power bumps pb2, and the second physical layer PHY2 connected to the second data bump db1. The second data bump db2 according to an embodiment may be in contact with and connected to the 2_0-th to 2_n-th data pads dp2_0 to dp2_n connected to the data line DL in FIG. 1 and FIG. 2 and configured to transmit and receive the second data signal DQ2.

In an embodiment, the second physical layer PHY2 may be connected to a portion of the plurality of first through-silicon vias TSV1 disposed on an upper surface of the buffer die 200, to transmit and receive data of the memory die 100. In an embodiment, the second physical layer PHY2 may include a serializer/deserializer SER/DES, and the serializer/deserializer SER/DES may input and output data to and from the memory die 100 through the second data signal DQ2. In an embodiment, the second physical layer PHY2 may be connected to a portion of the plurality of first through-silicon vias TSV1 and provide the power signal PWR to the memory die 100.

The second physical layer PHY2 may be disposed to overlap with at least a portion the plurality of second data bumps db2, the plurality of second command and address bumps cab2, and second power bump pb2, in a plan view, with respect to the third direction Z as a reference.

Each of the plurality of first bumps MB, each of the plurality of first direct access bumps dab, each of the plurality of first and second power bumps pb1 and pb2, each of the plurality of first and second command and address bumps cab1 and cab2, each of the plurality of first and second data bumps db1 and db2 and each of the plurality of first control signal bumps cdb may be a micro-bump.

In an embodiment, the interposer 30 may be disposed between the host device 10 and a PCB 40 and between the memory device 20 and the PCB 40. In an embodiment, a plurality of second direct access bumps DAFB, a plurality of third power bumps PBFB, and a plurality of second control signal bumps CDFB may be disposed on a lower surface of the interposer 30. The plurality of second direct access bumps DAFB, the plurality of third power bumps PBFB, and the plurality of second control signal bumps CDFB may be connected to the PCB 40.

The interposer 30 may include a silicon interposer, an organic interposer, or the like, but is not limited thereto. In an embodiment, the interposer 30 may be an active interposer including a logic circuit.

In an embodiment, the interposer 30 may include a redistribution structure 310 and a substrate 320. In an embodiment, the redistribution structure 310 may be disposed in an upper portion of the substrate 320 in the third direction Z.

In an embodiment, the substrate 320 may have an upper surface and a bottom surface facing each other, and may be a semiconductor wafer containing a semiconductor element such as silicon and germanium, or a compound semiconductor such as silicon carbide (SiC), gallium arsenide (GaAs), indium arsenide (InAs), and indium phosphide (InP). In an embodiment, the substrate 320 may include an active surface (e.g., upper surface) having an active region doped with impurities and an inactive surface (e.g., bottom surface) on the opposite side.

In an embodiment, the input/output tuning circuit 30c may be disposed in at least a portion of an upper surface of the substrate 320. The input/output tuning circuit 30c may include individual devices constituting an integrated circuit disposed on the upper surface of the substrate 320. In this case, the individual devices may be electrically connected to a redistribution layer 312 of the redistribution structure 310. In an embodiment, the input/output tuning circuit 30c may be connected to the plurality of first data bumps db1 and the plurality of second data bumps db2, through the data line DL. Although not shown, the input/output tuning circuit 30c may be connected to the plurality of first command and address bumps cab1.

The individual devices may include a field-effect transistor (FET) such as a planar FET, a FinFET, or the like, a memory device such as a flash memory, DRAM, static RAM (SRAM), electrically erasable programmable read-only memory (EEPROM), phase RAM (PRAM), magnetic RAM (MRAM), ferroelectric RAM (FeRAM), resistance RAM (RRAM), or the like, a logic device such as AND, OR, NOT or the like, and various active elements and/or passive elements such as system large-scale integration (LSI), contact image sensor (CIS), micro-electromechanical systems (MEMS), or the like.

The redistribution structure 310 may include the redistribution layer 312 and an insulation layer 314 that surrounds the redistribution layer 312. The redistribution layer 312 may be formed in a multi-layer structure that includes vas and conductive patterns made of, for example, aluminum (Al), gold (Au), cobalt (Co), copper (Cu), nickel (Ni), lead (Pb), tantalum (Ta), tellurium (Te), titanium (Ti), tungsten (W) or a combination thereof. A barrier layer (not shown) including titanium (Ti), titanium nitride (TiN), tantalum (Ta), or tantalum nitride (TaN) may be disposed between the insulation layer 314 and the conductive pattern and/or via.

The insulation layer 314 may include flowable oxide (FOx), Tonen Silazen (TOSZ), undoped silica glass (USG), borosilica glass (BSG), phosphosilicate glass (PSG), borophosphosilicate glass (BPSG), plasma-enhanced tetraethyl orthosilicate (PETEOS), fluorosilicate glass (FSG), high-density-plasma (HDP) oxide, plasma enhanced oxide (PEOX), flowable CVD (FCVD) oxide or a combination thereof. At least a partial region of the insulation layer 314 surrounding the redistribution layer 312 may be formed as a low dielectric layer. The insulation layer 314 may be formed by using chemical vapor deposition (CVD), flowable-CVD process or spin coating process.

In an embodiment, the redistribution layer 312 may include the data line DL connecting between the plurality of first data bumps db1 and the input/output tuning circuit 30c, and between the plurality of second data bumps db2 and the input/output tuning circuit 30c. In an embodiment, the redistribution layer 312 may connect the plurality of first command and address bumps cab1 and the plurality of second command and address bumps cab2, and may connect the plurality of first power bumps pb1 and the plurality of second power bumps pb2.

In an embodiment, the redistribution layer 312 may include a plurality of direct lines connected to a portion of a plurality of second through-silicon vias TSV2 penetrating at least a portion of the substrate 320 and the insulation layer 314 in the third direction Z and electrically connecting the plurality of first direct access bumps dab and the plurality of second direct access bumps DAFB, and a plurality of control signal lines connected to a portion of the plurality of second through-silicon vias TSV2 and electrically connecting the plurality of first control signal bumps cdb and the plurality of second control signal bumps CDFB. In an embodiment, the redistribution layer 312 may include a power line connected to a portion of the plurality of second through-silicon vias TSV2 and connecting between the plurality of third power bumps PBFB and the plurality of first power bumps pb1 of the host device 10.

A plurality of direct access balls DAB, a plurality of power balls PB, and a plurality of control signal balls CDB may be disposed on a lower surface of the PCB 40.

In an embodiment, in the PCB 40, the plurality of second direct access bumps DAFB and the plurality of direct access balls DAB may be connected, the plurality of third power bumps PBFB and the plurality of power balls PB may be connected, and the plurality of second control signal bumps CDFB and the plurality of control signal balls CDB may be connected.

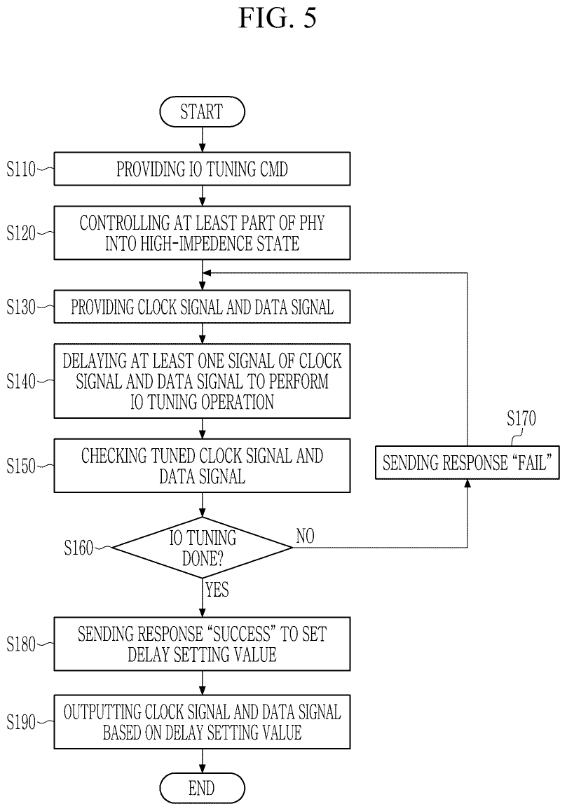

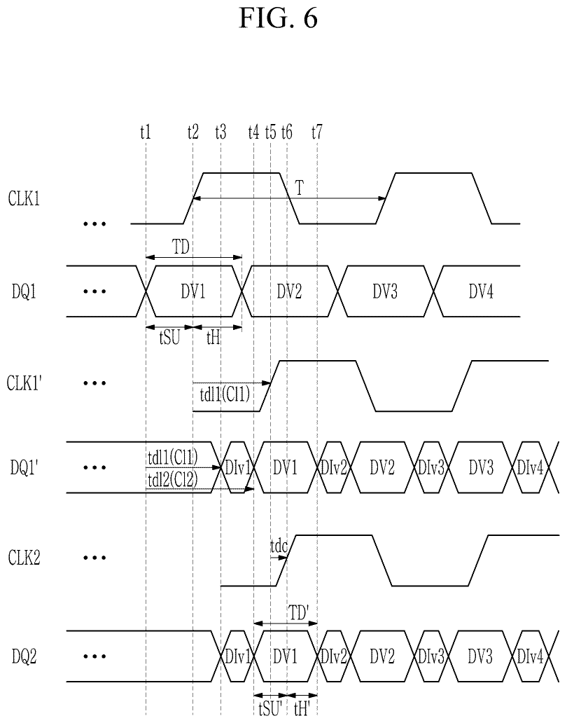

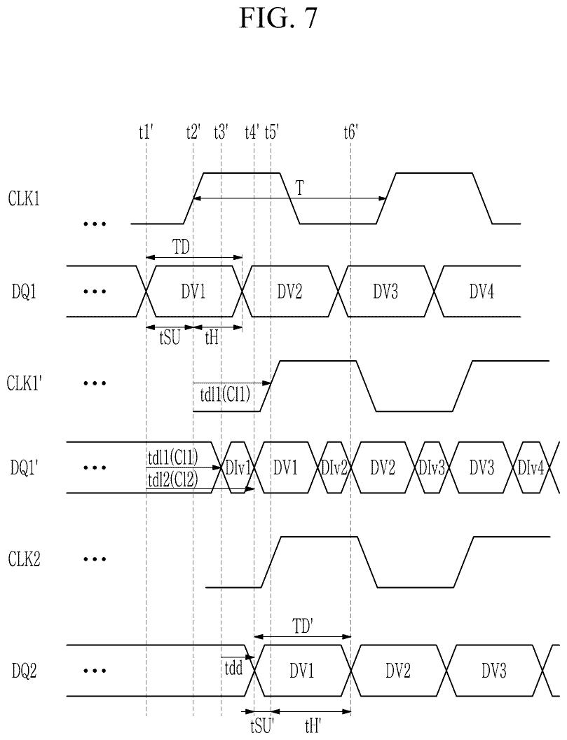

FIG. 5 is a flowchart showing an operation method of an integrated circuit package according to an embodiment. FIG. 6 is a timing diagram for explaining the input/output tuning operation of an integrated circuit package according to an embodiment. FIG. 7 is a timing diagram for explaining the input/output tuning operation of an integrated circuit package according to an embodiment.

Referring to FIGS. 1 to 5, at step S110, the host device 10 may provide the input/output tuning command IT_CMD to the memory device 20. In an embodiment, the host device 10 may provide the input/output tuning command IT_CMD to the memory device 20 and the input/output tuning circuit 30c.

In an embodiment, the host device 10 may output the input/output tuning command IT_CMD according to a boot-on time point or predetermined tuning update cycle, and provide it to the memory device 20 and the input/output tuning circuit 30c.

At step S120, the memory device 20 may control a portion of the second physical layer PHY2 to a high-impedance state, in response to the reception of the input/output tuning command IT_CMD.

In an embodiment, the memory device 20 may control such that the second clock pad cp2 and the 2_0-th to 2_n-th data pads dp2_0 to dp2_n of the second physical layer PHY2 may be seen to be the high-impedance state. Through the control operation, the memory device 20 may block the signal input from the second clock pad cp2 and the 2_0-th to 2_n-th data pads dp2_0 to dp2_n in response to the reception of the input/output tuning command IT_CMD. Through the operation of the step S120, an operation of the input/output tuning circuit 30c at step S130 to step S190 to be described later may be efficiently performed.

At step S130, the host device 10 may provide the first clock signal CLK1 and the first data signal DQ1 to the input/output tuning circuit 30c, after the outputting of the input/output tuning command IT_CMD.

In an embodiment, the host device 10 may provide the tuning block signal for the input/output tuning operation together with the first clock signal CLK1. The data signal included in the tuning block signal may include a predetermined data pattern.

At step S140, the delay circuit 32 may delay at least one of the first clock signal CLK1 and the first data signal DQ1, and perform the input/output tuning operation.

FIG. 6 is a timing diagram for explaining an example of the input/output tuning operation of the delay circuit 32. Referring to FIG. 6 as an example, at a time point t1, the host device 10 may output the first data signal DQ1. In an embodiment, the host device 10 may output the first clock signal CLK1 synchronously with the first data signal DQ1, and the first clock signal CLK1 may be output by toggling with a clock period T.

After the time point t1, the host device 10 may sequentially output first to fourth valid data DV1 to DV4 as the first data signal DQ1, with a period of a data section TD, which is a half of the clock period T. In an embodiment, the first to fourth valid data DV1 to DV4 may be the tuning block of the predetermined data pattern.

At a time point t2, the first clock signal CLK1 may increase from the logical low to the logical high, and the data section TD corresponding to a remainder after the time point t2 may be a hold section tH. The time point t2 may be a time point at which a setup section tSU has elapsed from the time point t1.

After a time point t3, in response to the output of the first to fourth valid data DV1 to DV4, the delay circuit 32 may sequentially receive a first invalid data DIv1, a first valid data DV1, a second invalid data DIv2, a second valid data DV2, a third invalid data DIv3, a third valid data DV3, a fourth invalid data DIv4, and a fourth valid data DV4, as a first delay data signal DQ1′.

Referring to FIG. 2 together, as an example, the first clock signal CLK1 and each of the 1_0-th to 1_n-1-th data signals DQ1[n-1:0] may be delayed by a first wire delay time tdl1 by the first wire capacitor Cl1, and provided to the clock delay circuit 32_c and the 0-th to n-1-th delay circuits 32_0 to 32_n-1 as the first delay clock signal CLK1′ and the 1_0-th to 1_n-1-th delay data signals DQ1[n-1:0]′. In addition, the 1_n-th data signal DQ1[n] may be delayed by a second wire delay time tdl2 by the second wire capacitor Cl2, and provided to the n-th delay circuit 32_n as the 1_n-th delay data signal DQ1[n]′.

At the time point t3, the 1_n-th delay data signal DQ1[n]′ of the first valid data DV1 does not reach the n-th delay circuit 32_n, and the delay circuit 32 may receive the first invalid data DIv1 as the first delay data signal DQ1′. The time point t3 may be a time point at which the first wire delay time tdl1 has elapsed from the time point t1.

At a time point t4, the delay circuit 32 may receive the first valid data DV1 as the first delay data signal DQ1′. The time point t4 may be a time point at which the second wire delay time tdl2 has elapsed from the time point t1.

In the same way, at a time point t5, the first delay clock signal CLK1′ may increase from the logical low to the logical high. The time point t5 may be a time point at which the first wire delay time tdl1 has elapsed from the time point t2.

The delay circuit 32 may delay the first delay clock signal CLK1′ by a clock delay time tdc, and may output the second clock signal CLK2 and the second data signal DQ2 based on the first delay clock signal CLK1′ and the first delay data signal DQ1′.

Through the delay operation of the delay circuit 32 with respect to the first delay clock signal CLK1′, a phase difference correspond to the clock delay time tdc may occur between the first delay clock signal CLK1′ and the second clock signal CLK2. The phase difference may not occur between the 1_0-th to 1_n-th delay data signals DQ1[n:0]′ and the 2_0-th to 2_n-th data signals DQ2[n:0]. In an embodiment, phase differences between each of the 1_0-th to 1_n-th delay data signals DQ1[n:0]′ and each of the 2_0-th to 2_n-th data signals DQ2[n:0] may be the same.

At a time point t6, the second clock signal CLK2 may increase from the logical low to the logical high. The time point t6 may be a time point at which an effective setup section tSU′ has elapsed from the time point t4.

The delay circuit 32 may output the first valid data DV1 as the second data signal DQ2, during a data-valid section TD′ from the time point t4 to a time point t7 at which the second invalid data DIv2 is output. A section from the time point t6 to the time point t7, which is the data-valid section TD′ corresponding to a remainder after the time point t6 may be an effective hold section tH′.

Referring back to FIG. 5, at the step S140, the delay circuit 32 may perform the input/output tuning operation for delaying the first delay clock signal CLK1′ corresponding to the first clock signal CLK1. Through the input/output tuning operation, the delay circuit 32 may adjust the time interval of the setup section and the hold section during the data-valid section to improve the skew between the clock signal and the data signal, and may reduce the error occurring during data transmission between the host device 10 and the memory device 20.

FIG. 7 is a timing diagram for explaining an example of the input/output tuning operation of the delay circuit 32. An output operation of the first clock signal CLK1 and the first data signal DQ1 and a reception operation of the first delay clock signal CLK1′ and the first delay data signal DQ1′ in a range from a time point t1′ to a time point t5′ of FIG. 7 may correspond to the output operation of the first clock signal CLK1 and the first data signal DQ1 and the reception operation of the first delay clock signal CLK1′ and the first delay data signal DQ1′ in a range from the time point t1 to the time point t5 of FIG. 6. For ease of description, FIG. 7 will be described focusing on an output operation of the second clock signal CLK2 and the second data signal DQ2.

Referring to FIG. 7 as an example, the delay circuit 32 may delay the 1_0-th to 1_n-1-th delay data signals DQ1[n-1:0]′ by a data delay time tdd, and may output the second clock signal CLK2 and the second data signal DQ2 based on the first delay clock signal CLK1′ and the first delay data signal DQ1′.

Through the delay operation of the delay circuit 32 with respect to the 1_0-th to 1_n-1-th delay data signals DQ1[n-1:0]′, a phase difference corresponding to the data delay time tdd may occur between each of the 1_0-th to 1_n-1-th delay data signals DQ1[n-1:0]′ and each of 2_0-th to 2_n-1-th data signals DQ2[n:0-1]. The phase difference may not occur between the first delay clock signal CLK1′ and the second clock signal CLK2 and between the 1_n-th delay data signal DQ1[n]′ and a 2_n-th delay data signal DQ2[n]. In an embodiment, a phase difference between the first delay clock signal CLK1′ and the second clock signal CLK2 may be the same as a phase difference between the 1_n-th delay data signal DQ1[n]′ and the 2_n-th delay data signal DQ2[n].

After a time point t4′, the delay circuit 32 may sequentially output the first to fourth valid data DV1 to DV4 as the second data signal DQ2, with a period of the data-valid section TD′. By the delay circuit 32 and the first and second wire capacitors Cl1 and Cl2, the first data signal DQ1 may be delayed by the second wire delay time tdl2, and output to the second data signal DQ2. In an embodiment, the delay circuit 32 may sequentially output a plurality of valid data as the second data signal DQ2 without involvement of invalid data.

At the time point t5′, the second clock signal CLK2 may increase from the logical low to the logical high. The time point t5′ may be a time point at which the effective setup section tSU′ has elapsed from the time point t4′.

The delay circuit 32 may output the first valid data DV1 as the second data signal DQ2, during the data-valid section TD′ from the time point t4′ to a time point t6′ at which the second valid data DV2 is output. A section from the time point t5′ to the time point t6′, which is the data-valid section TD′ corresponding to a remainder after the time point t5′ may be an effective hold section tH′.

Referring back to FIG. 5, at the step S140, the delay circuit 32 may perform the input/output tuning operation for delaying a portion of the first delay data signal DQ1′ corresponding to the first data signal DQ1. Through the input/output tuning operation, the delay circuit 32 may secure the time interval of the data-valid section, thereby improving a margin of a data-valid window with respect to the data signal, and may reduce the error occurring during data transmission between the host device 10 and the memory device 20.

At step S150, the data checker 31C may check the data-valid section with respect to the second clock signal CLK2 and the second data signal DQ2 on which the input/output tuning operation has been performed.

The data checker 31C may receive the second clock signal CLK2 and the second data signal DQ2, and may perform a check operation for measuring a time interval of the data-valid section TD′ and the effective setup section tSU′ with respect to the second data signal DQ2 of FIG. 6 and FIG. 7.

At step S160, the data checker 31C may determine whether the input/output tuning operation has been completed, based on the result of the check operation.

In an embodiment, the data checker 31C may compare the time interval of the measured data-valid section TD′ with a predetermined first time interval, and when the time interval of the data-valid section TD′ is longer than the predetermined first time interval, the data checker 31C may determine that the input/output tuning operation has been completed.

In an embodiment, the data checker 31C may compare the time interval of the measured effective setup section tSU′ with a predetermined second time interval, and when the time interval of the effective setup section tSU′ is longer than the predetermined second time interval, the data checker 31C may determine that the input/output tuning operation has been completed.

In an embodiment, the data checker 31C may determine that the input/output tuning operation has been completed when a condition on the data-valid section TD′ and a condition on the effective setup section tSU′ are all satisfied, but in an embodiment, it may determine that the input/output tuning operation has been completed when one of the conditions is satisfied.

At step S170, the data checker 31C may check the data-valid section with respect to the second data signal DQ2, and when it is determined based on the result of the check operation that the input/output tuning operation has not been completed, it may provide the response signal Rsp of the fail to the host device 10.

According to the provision of the response signal Rsp of the fail, the integrated circuit package 1a may repeatedly perform the step S130 to the step S160, while changing the selection signal SS of the delay selector 31S.

At step S180, the data checker 31C may check the data-valid section with respect to the second data signal DQ2, and when it is determined based on the result of the check operation that the input/output tuning operation has been completed, it may provide the response signal Rsp of success to the host device 10 and set the delay setting value DSV.

The data checker 31C may set the delay setting value DSV based on the selection signal SS corresponding to the completion of the input/output tuning operation determination. In an embodiment, when the data checker 31C provides the response signal Rsp of success to the host device 10, the data checker 31C may set the delay setting value DSV based on the clock selection signal SS_c and the 0-th to n-th selection signals SS_0 to SS_n, and may provide the predetermined delay setting value DSV to the delay selector 31S.

Thereafter, the second physical layer PHY2 of which a portion is controlled to the high-impedance state at the step S120 may be controlled to a data input/output state for the write operation and the read operation.

At step S190, the delay circuit 32 may output the second clock signal CLK2 and the second data signal DQ2 based on the predetermined delay setting value DSV.

The delay selector 31S may output the selection signal SS, based on the predetermined delay setting value DSV and provide it to the delay circuit 32. In an embodiment, the delay circuit 32 may perform the input/output tuning operation based on the received selection signal SS, to output the second clock signal CLK2 and the second data signal DQ2 and provide it to the memory device 20.

Through the step S110 to the step S190, the integrated circuit package 1a according to an embodiment may improve a margin of a data-valid window with respect to the data signals DQ1 and DQ2 transmitted and received between the host device 10 and the memory device 20, and may improve the skew between the clock signals CLK1 and CLK2 and the data signals DQ1 and DQ2, thereby reducing data error generated during data transmission.

At the step S140, it has been described that the input/output tuning operation of FIG. 6 and the input/output tuning operation of FIG. 7 are performed in different embodiments, but in an embodiment, the integrated circuit package 1a may perform the input/output tuning operation of FIG. 6 and the input/output tuning operation of FIG. 7, in a combination.

In an embodiment, by the delay circuit 32 and the first and second wire capacitors Cl1 and Cl2, the first data signal DQ1 and the first clock signal CLK1 may be delayed by the second wire delay time tdl2 and output the second clock signal CLK2 and the second data signal DQ2 based on the first delay clock signal CLK1′ and the first delay data signal DQ1′. Accordingly, through the input/output tuning operation, the delay circuit 32 may secure the time interval of the data-valid section, thereby improving a margin of a data-valid window with respect to the data signal, and may reduce the error occurring during data transmission between the host device 10 and the memory device 20.

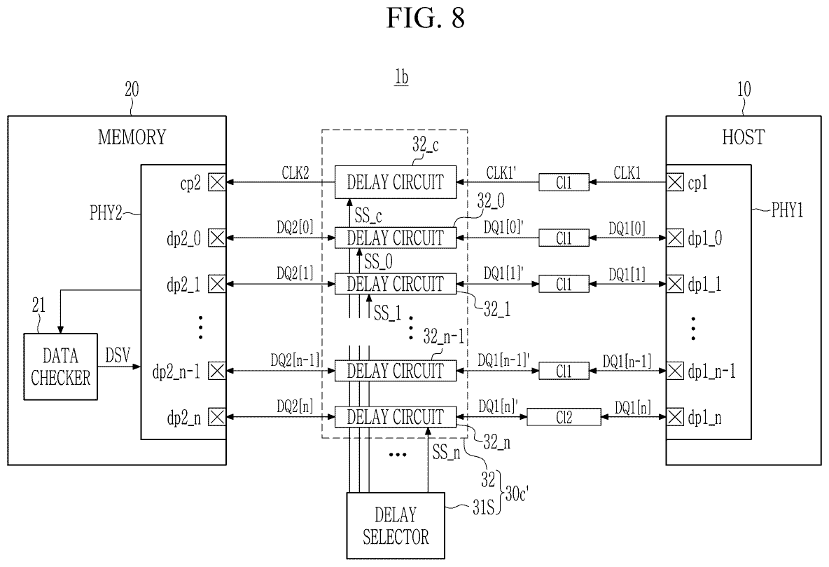

FIG. 8 is a block diagram showing an integrated circuit package according to an embodiment. Each of the host device 10, a memory device 20′, and the input/output tuning circuit 30c′ within an integrated circuit package 1b of FIG. 8 may correspond to the host device 10, the memory device 20, and the input/output tuning circuit 30c within the integrated circuit package 1a of FIG. 2, respectively. For ease of description, the integrated circuit package 1b of FIG. 8 will be described focusing on the difference from the integrated circuit package 1a of FIG. 2, and the features common with the integrated circuit package 1a of FIG. 2 may be referred to the description made with reference to FIG. 2.

Referring to FIGS. 1, 3, 4 and 8, the integrated circuit package 1b may include the host device 10, the memory device 20′, and the input/output tuning circuit 30c′.

Compared to the memory device 20 of FIG. 2, the memory device 20′ may further include a data checker 21. The data checker 21 may correspond to the data checker 31C of FIG. 2. In an embodiment, the input/output tuning circuit 30c′ may include the delay selector 31S and the delay circuit 32, without an arrangement of a separate data checker.

In an embodiment, the data checker 21 may check the data-valid section of the second data signal DQ2 based on the second clock signal CLK2 and the 2_0-th to 2_n-th data signals DQ2[n:0] input through the second clock pad cp2 and the 2_0-th to 2_n-th data pads dp2_0 to dp2_n within the second physical layer PHY2.

In an embodiment, the data checker 21 may determine the completion of the input/output tuning operation, according to the result of the check operation with respect to the data-valid section. In an embodiment, the data checker 21 may provide the result of the determination to the host device 10 as the response signal Rsp through the data line DL.

In an embodiment, the data checker 21 within the memory device 20′ may provide the predetermined delay setting value DSV to the delay selector 31S, through the data line DL.

The memory device 20′ of the integrated circuit package 1b according to an embodiment may include the data checker 21, and perform the check operation of the data-valid section based on the second clock signal CLK2 and the second data signal DQ2 input to the memory device 20′, thereby increasing the reliability of the input/output tuning operation.

In an embodiment, the data checker 21 may be disposed to be separate from the delay circuit 32 and the delay selector 31S.

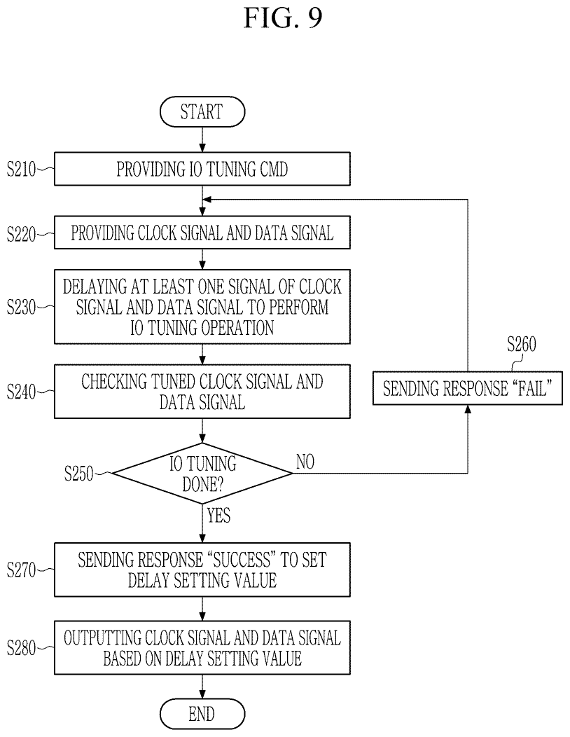

FIG. 9 is a flowchart showing an operation method of an integrated circuit package according to an embodiment. Steps S210, S220, S230, S240, S250, S260, S270 and S280 of FIG. 9 may correspond to, respectively the steps S110, S130, S140, S150, S160, S170, S180 and S190 of FIG. 5. For ease of description, steps of the operation method of FIG. 9 will be described focusing on the difference from operation method of FIG. 5, and the features common with operation method of FIG. 5 may be referred to the description made with reference to FIG. 5.

Referring to FIGS. 1, 3, 4, 8 and 9, at the step S210, the host device 10 may provide the input/output tuning command IT_CMD to the memory device 20′. The step S210 may correspond to the step S110 of FIG. 5.

At step S220, the host device 10 may provide the first clock signal CLK1 and the first data signal DQ1 to the input/output tuning circuit 30c′, after the outputting of the input/output tuning command IT_CMD. The step S220 may correspond to the step S130 of FIG. 5.

Before the step S220, the memory device 20′ may not control a portion of the second physical layer PHY2 to a high-impedance state, in response to the reception of the input/output tuning command IT_CMD.

At step S230, the delay circuit 32 may delay at least one of the first clock signal CLK1 and the first data signal DQ1, and perform the input/output tuning operation. The step S230 may correspond to the step S140 of FIG. 5.

At step S240, the data checker 21 may check the data-valid section with respect to the second clock signal CLK2 and the second data signal DQ2 on which the input/output tuning operation has been performed. The step S240 may correspond to the step S150 of FIG. 5.

The data checker 21 may receive the second clock signal CLK2 and the second data signal DQ2 input through the second physical layer PHY2, and may check the data-valid section with respect to the second clock signal CLK2 and the second data signal DQ2.

At step S250, the data checker 21 may determine whether the input/output tuning operation has been completed, based on the result of the check operation. The step S250 may correspond to the step S160 of FIG. 5.

At step S260, the data checker 21 may check the data-valid section with respect to the second data signal DQ2, and when it is determined based on the result of the check operation that the input/output tuning operation has not been completed, it may provide the response signal Rsp of the fail to the host device 10. The step S260 may correspond to the step S170 of FIG. 5.

At step S270, the data checker 21 may check the data-valid section with respect to the second data signal DQ2, and when it is determined based on the result of the check operation that the input/output tuning operation has been completed, may provide the response signal Rsp of success to the host device 10 and set the delay setting value DSV. The step S270 may correspond to the step S180 of FIG. 5.

In an embodiment, when the data checker 21 provides the response signal Rsp of success to the host device 10, the data checker 21 may set the delay setting value DSV based on the clock selection signal SS_c and the 0-th to n-th selection signals SS_0 to SS_n, and may provide the predetermined delay setting value DSV to the delay selector 31S through the data line DL.

At the step S270, the second physical layer PHY2 may be controlled to a data input/output state for the write operation and the read operation, without a separate change of the impedance state.

At step S280, the delay circuit 32 may output the second clock signal CLK2 and the second data signal DQ2 based on the predetermined delay setting value DSV. The step S280 may correspond to the step S190 of FIG. 5.

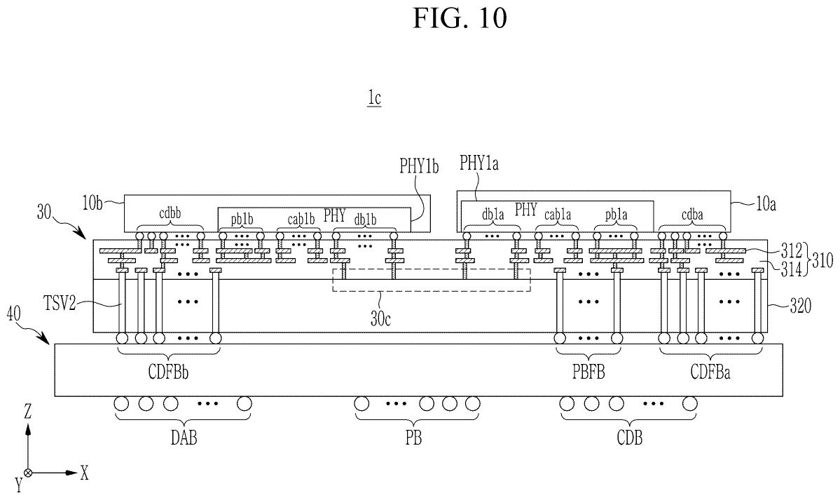

FIG. 10 is a drawing for explaining an integrated circuit package according to an embodiment. Each of an a-th chiplet 10a, a b-th chiplet 10b, the interposer 30, and the PCB 40 within an integrated circuit package 1c of FIG. 10 may correspond to the host device 10, the memory device 20, the interposer 30, and the PCB 40 within the integrated circuit package 1a of FIG. 4, respectively. For ease of description, the integrated circuit package 1c of FIG. 10 will be described focusing on the difference from the integrated circuit package 1a of FIG. 4, and the features common with the integrated circuit package 1a of FIG. 4 may be referred to the description made with reference to FIG. 4.

Referring to FIGS. 1 to 3 and 10, the a-th chiplet 10a, the b-th chiplet 10b, the interposer 30, and the PCB 40 may be included within the integrated circuit package 1c.

The a-th chiplet 10a and the b-th chiplet 10b each may include at least one function block.

The term “function block” may refer to a unit block that is also known as intellectual property (IP) and is divided into function units that can actually be developed. In an embodiment, each of the a-th chiplet 10a and the b-th chiplet 10b may be a chiplet forming the function blocks as separate semiconductor chips.

In an embodiment, the a-th chiplet 10a and the b-th chiplet 10b may have different function blocks, may be disposed on the interposer 30 to be spaced apart from each other in the first direction X, and may be mounted on the interposer 30. In an embodiment, the a-th chiplet 10a and the b-th chiplet 10b may operate as one logic semiconductor chip, and may transmit and receive the clock signal and the data signal with each other.

A plurality of 1_a-th command and address bumps cab1a, a plurality of 1_a-th data bumps db1a, a plurality of 1_a-th power bumps pb1a, and a plurality of 1_a-th control signal bumps cdba may be disposed on the lower surface of the a-th chiplet 10a. In an embodiment, the a-th chiplet 10a may include the plurality of 1_a-th command and address bumps cab1a, the plurality of 1_a-th data bumps db1a, and a 1_a-th physical layer PHY1a connected to the plurality of 1_a-th power bumps pb1a. The plurality of 1_a-th command and address bumps cab1a, the plurality of 1_a-th data bumps db1a, and the plurality of 1_a-th power bumps pb1a each may correspond to the plurality of first command and address bumps cab1, the first data bump db1, and the plurality of first power bumps pb1 of FIG. 4.

A plurality of 1_b-th command and address bumps cab1b, a plurality of 1_b-th data bumps db1b, a plurality of 1_b-th power bumps pb1b, and a plurality of 1_b-th control signal bumps cdbb may be disposed on the lower surface of the b-th chiplet 10b. In an embodiment, the b-th chiplet 10b may include the plurality of 1_b-th command and address bumps cab1b, the plurality of 1_b-th data bumps db1b, and a 1_b-th physical layer PHY 1b connected to the plurality of 1_b-th power bumps pb1b. The plurality of 1_b-th command and address bumps cab1b, the plurality of 1_b-th data bumps db1b, the plurality of 1_b-th power bumps pb1b may correspond to the plurality of second command and address bumps cab2, the second data bump db2, and the plurality of second power bumps pb2 of FIG. 4, respectively.

The 1_a-th physical layer PHY1a and the 1_b-th physical layer PHY1b may be a UCIe PHY based on Universal Chiplet Interconnect Express (UCIe) open-type standard, but is not limited thereto. In an embodiment, the 1_a-th physical layer PHY1a and the 1_b-th physical layer PHY 1b may transmit and receive the clock signals CLK1 and CLK2 and the data signals DQ1 and DQ2, through the interposer 30.

The plurality of 1_a-th data bumps db1a and the plurality of 1_b-th data bumps db1b may be electrically connected to the input/output tuning circuit 30c through the data line DL included in the redistribution structure 310. The a-th chiplet 10a and the b-th chiplet 10b may transmit and receive the clock signal and the data signal, through the input/output tuning circuit 30c.

In an embodiment, the a-th chiplet 10a may output the first clock signal CLK1 and the first data signal DQ1. As shown in FIGS. 5 to 7, the input/output tuning circuit 30c may perform the input/output tuning operation for delaying at least a portion of the first clock signal CLK1 and the first data signal DQ1, to output the second clock signal CLK2 and the second data signal DQ2 and provide it to the b-th chiplet 10b.

The integrated circuit package 1c according to an embodiment may improve a margin of a data-valid window with respect to the data signals DQ1 and DQ2 transmitted and received between the a-th chiplet 10a and the b-th chiplet 10b through the input/output tuning operation of the input/output tuning circuit 30c, and may improve the skew between the clock signals CLK1 and CLK2 and the data signals DQ1 and DQ2, thereby reducing data error generated during data transmission.

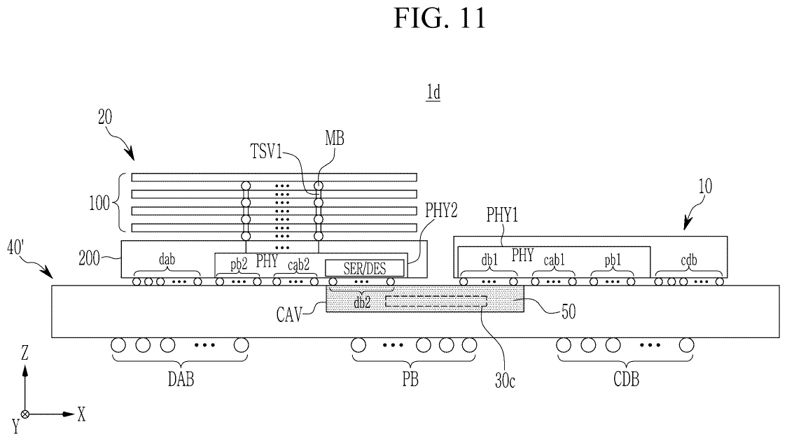

FIG. 11 is a drawing for explaining an integrated circuit package according to an embodiment. Each of the host device 10, the memory device 20, a bridge chip 50, and a PCB 40′ within an integrated circuit package 1d of FIG. 11 may correspond to the host device 10, the memory device 20, the interposer 30, and the PCB 40 within the integrated circuit package 1a of FIG. 4, respectively. For ease of description, the integrated circuit package 1d of FIG. 11 will be described focusing on the difference from the integrated circuit package 1a of FIG. 4, and the features common with the integrated circuit package 1a of FIG. 4 may be referred to the description made with reference to FIG. 4.

Referring to FIGS. 1 to 3, and 11, the host device 10, the memory device 20, the bridge chip 50, and the PCB 40′ may be included in the integrated circuit package 1d. The host device 10 and the memory device 20 may be arranged and mounted on the PCB 40′. The host device 10 and the memory device 20 may be disposed to be spaced apart from each other in the first direction X, and non-overlapping with each other in a plan view with respect to the third direction Z as a reference.

The bridge chip 50 may be disposed to be accommodated within a cavity CAV formed on an upper surface of the PCB 40′. In an embodiment, the bridge chip 50 may include the input/output tuning circuit 30c.

The bridge chip 50 may be disposed to overlap with at least a portion of the host device 10 and at least a portion of the memory device 20, with respect to the third direction Z as a reference. The bridge chip 50 may be connected to the plurality of first data bumps db1 disposed on the lower surface of the host device 10 and the plurality of second data bumps db2 disposed on the lower surface of the buffer die 200. In an embodiment, the bridge chip 50 may include the data line DL connecting between the plurality of first data bumps db1 and the input/output tuning circuit 30c, and between the plurality of second data bumps db2 and the input/output tuning circuit 30c.

In an embodiment, the PCB 40′ may connect the plurality of first command and address bumps cab1 and the plurality of second command and address bumps cab2, and may connect the plurality of first power bumps pb1 and the plurality of second power bumps pb2.

In an embodiment, the PCB 40′ may include a direct line electrically connecting the plurality of direct access balls DAB and the plurality of first direct access bumps dab, and the plurality of control signal lines electrically connecting the plurality of control signal balls CDB and the plurality of first control signal bumps cdb. In an embodiment, the PCB 40′ may include a power line connecting between the plurality of power balls PB and the plurality of first power bumps pb1 of the host device 10.

Through the input/output tuning operation of the input/output tuning circuit 30c, the integrated circuit package 1d according to an embodiment may improve a margin of a data-valid window with respect to the data signals DQ1 and DQ2 transmitted and received between the host device 10 and the memory device 20, and may improve the skew between the clock signals CLK1 and CLK2 and the data signals DQ1 and DQ2, thereby reducing data error generated during data transmission.

While the invention has been described in connection with what is presently considered to be practical embodiments, it is to be understood that the invention is not limited to the disclosed embodiments. On the contrary, it is intended to cover various modifications and equivalent arrangements included within the spirit and scope of the present invention as set forth in the appended claims.

What is claimed is:

1. An integrated circuit package, comprising:
a substrate;
a first semiconductor chip disposed on the substrate and configured to output a first clock signal and a first data signal;
a delay circuit configured to delay at least one of the first clock signal and the first data signal, and to output a second clock signal and a second data signal based on the first clock signal and the first data signal; and
a second semiconductor chip disposed on the substrate to be horizontally spaced apart from the first semiconductor chip and configured to receive the second clock signal and the second data signal.

2. The integrated circuit package of claim 1, further comprising:
a data checker configured to receive the second clock signal and the second data signal, and perform an operation to check a data-valid section with respect to the second data signal.

3. The integrated circuit package of claim 2, wherein the data checker is configured to compare an effective setup section within the data-valid section with a predetermined time interval, based on the second clock signal.

4. The integrated circuit package of claim 2, wherein the second semiconductor chip includes the data checker.

5. The integrated circuit package of claim 1, further comprising:
an active interposer disposed between the substrate and the first semiconductor chip and configured to mount the first and second semiconductor chips,
wherein the active interposer includes the delay circuit.

6. The integrated circuit package of claim 1, further comprising:
a bridge chip connected to the first and second semiconductor chips and including the delay circuit,
wherein the bridge chip is disposed in a cavity formed on a first surface of the substrate.

7. The integrated circuit package of claim 6, wherein the first and second semiconductor chips are mounted on the substrate.

8. The integrated circuit package of claim 1, wherein each of the first and second semiconductor chips is a chiplet including at least one function block.

9. The integrated circuit package of claim 1, wherein:
the first data signal includes a third data signal and a fourth data signal each including 1 bit of data,
the second data signal includes a fifth data signal and a sixth data signal output from the delay circuit based on the third and fourth data signals, and
the delay circuit includes a first delay circuit configured to output the fifth data signal based on the third data signal, a second delay circuit configured to output the sixth data signal based on the fourth data signal, and a clock delay circuit configured to output the second clock signal based on the first clock signal.

10. The integrated circuit package of claim 9, wherein the first delay circuit comprises:
a first delay buffer configured to output a first delay buffer signal by delaying the third data signal by a predetermined delay time;
a second delay buffer configured to output a second delay buffer signal by delaying the first delay buffer signal by the predetermined delay time; and
a multiplexer configured to select one of the third data signal, the first delay buffer signal, and the second delay buffer signal as the fifth data signal in response to a selection signal.

11. The integrated circuit package of claim 10, further comprising:
a delay selector configured to provide the selection signal to the multiplexer.

12. The integrated circuit package of claim 9, wherein:
the fifth data signal is generated by performing a delay operation on the third data signal, and
a phase difference between the sixth data signal and the fourth data signal is the same as a phase difference between the second clock signal and the first clock signal.

13. The integrated circuit package of claim 9, wherein:
the second clock signal is generated by performing a delay operation on the first clock signal, and
a phase difference between the fifth data signal and the third data signal is the same as a phase difference between the sixth data signal and the fourth data signal.

14. An integrated circuit package, comprising:
a first semiconductor chip configured to output a first clock signal and a first data signal;
an active interposer connected to the first semiconductor chip, and including a delay circuit configured to:
delay at least one of the first clock signal and the first data signal, and
output a second clock signal and a second data signal; and
a second semiconductor chip disposed on the active interposer to be horizontally spaced apart from the first semiconductor chip, and configured to receive the second clock signal and the second data signal.

15. The integrated circuit package of claim 14, further comprising:
first and second memory dies disposed perpendicular to each other on the second semiconductor chip,
wherein the first semiconductor chip is a logic chip, and
wherein the second semiconductor chip is a buffer die with respect to the first and second memory dies.

16. The integrated circuit package of claim 14, wherein the active interposer further includes:
a substrate on which the delay circuit is disposed;
a redistribution layer configured to provide the first clock signal and the first data signal from the first semiconductor chip to the delay circuit; and
a through via vertically penetrating at least a portion of the substrate.

17. The integrated circuit package of claim 16, wherein the redistribution layer is configured to provide the second clock signal and the second data signal from the delay circuit to the first semiconductor chip.

18. The integrated circuit package of claim 14, wherein the active interposer further includes a data checker configured to:
receive the second clock signal and the second data signal, and
perform an operation to check a data-valid section with respect to the second data signal.

19. An operation method of an integrated circuit package, the operation method comprising:
receiving an input/output tuning command from a first semiconductor chip mounted on a substrate;
receiving a first clock signal and a first data signal from the first semiconductor chip, in response to the reception of the input/output tuning command;
performing an input/output tuning operation by delaying at least one of the first clock signal and the first data signal to output a second clock signal and second data signal;
checking a data-valid section with respect to the second data signal, based on the second clock signal and the second data signal;
setting a delay setting value with respect to the input/output tuning operation, in response to result of the checking; and
outputting the second clock signal and the second data signal, based on the delay setting value.

20. The operation method of claim 19, further comprising:
controlling at least a portion of a second semiconductor chip receiving the second data signal to be a high-impedance state, in response to the reception of the input/output tuning command.
